(19) United States
(12) Patent Application Publication
(10) Pub. No.: US 2007/0096124 A1
(43) Pub. Date: May 3, 2007

(54) Array substrate for a display panel, method of manufacturing the same, display panel having the same and liquid crystal display device having the same

(75) Inventors: Won-Suk Shin, Yongin-si (KR); Hong-Sick Park, Suwon-si (KR); Jong-Hyun Choung, Suwon-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/544,087

(22) Filed: Oct. 6, 2006

(30) Foreign Application Priority Data
Oct. 11, 2005 (KR) 2005-95274

(51) Int. Cl. H01L 33/00; H01L 29/18

(52) U.S. Cl. 257/88

(57) ABSTRACT

An array substrate for a display panel includes a base substrate, a signal-applying module, a first electrode, a second electrode, and a protective layer. The signal-applying module is disposed on the base substrate and includes an output terminal to output a data signal. The first electrode is disposed on the base substrate and electrically connected to the output terminal. The second electrode includes silver (Ag), and is disposed on and electrically connected to the first electrode. The protective layer is disposed on the second electrode to cover a portion of the second electrode. Thus, adhesion of the second electrode to a lower layer may be improved, and yellowishness of the second electrode may be prevented.

### CROSS-REFERENCE TO RELATED APPLICATIONS

This application relies for priority upon Korean Patent Application No. 2005-95274 filed on Oct. 11, 2005, the contents of which are herein incorporated by reference in their entireties.

### BACKGROUND OF THE INVENTION

1. Field of the Invention

The present invention relates to an array substrate for a display panel, a method of manufacturing the array substrate, a display panel having the array substrate, and a liquid crystal display device having the array substrate. More particularly, the present invention relates to an array substrate for a display panel capable of improving adhesion to a layer and preventing yellowishness, a method of manufacturing the array substrate, a display panel having the array substrate and a liquid crystal display device having the array substrate.

2. Description of the Related Art

Generally, a display device converts information processed from an information processing device to an image.

Examples of the display device include a cathode ray tube (CRT) type display device, a liquid crystal display (LCD) device, an organic light emitting display (OLED) device, etc.

The LCD device is classified into a transmissive type LCD device, a reflective type LCD device and a reflective-transmissive type LCD device according to a method of using light.

The transmissive type LCD device displays an image using light internally provided from a lamp installed in the LCD device. The reflective type LCD device displays an image using light externally provided from the sun, an illumination device, etc. The reflective-transmissive type LCD device displays an image using light internally provided from a lamp installed in the LCD device and/or externally provided from the sun, an illumination device, etc.

The transmissive type LCD device includes a transparent conductive transparent electrode, and the reflective type LCD device includes a reflective electrode that has a greater reflectivity than a transparent electrode. The reflective-transmissive type LCD device includes both a transparent electrode and a reflective electrode.

The reflective electrode employed in the reflective type LCD device and the reflective-transmissive type LCD device may preferably include a material having a great reflectivity. Thus, the reflective electrode usually includes aluminum (Al) or aluminum alloy having a great reflectivity.

Recently, serving silver (Ag) as the reflective electrode has been studied since silver has a greater reflectivity than aluminum. However, silver has a low adhesion to a lower layer, and may become yellowish through following processes.

### SUMMARY OF THE INVENTION

Embodiments of the present invention obviate the above problems and thus the present invention provides an array substrate capable of improving adhesion to a layer and preventing electrode yellowishness.

Embodiments of the present invention also provide a method of manufacturing the above-mentioned array substrate.

Embodiments of the present invention also provide a display panel having the above-mentioned array substrate.

Embodiments of the invention also provide a liquid crystal display device having the above-mentioned array substrate.

In one aspect of the present invention, an array substrate for a display panel includes a base substrate, a signal-applying module, a first electrode, a second electrode, and a protective layer. The signal-applying module is disposed on the base substrate, and includes an output terminal configured to output a data signal. The first electrode is disposed on the base substrate and electrically connected to the output terminal. The second electrode is disposed on the first electrode and electrically connected to the first electrode. The second electrode includes silver (Ag). The protective layer is disposed on the second electrode to cover at least a portion of the second electrode.

In another aspect of the present invention, in order to manufacture an array substrate for a display panel, a signal-applying module including an output terminal configured to output a data signal is formed on a base substrate. A contact hole that exposes a portion of the output terminal is formed through an insulation layer covering the signal-applying module to form an insulation pattern. A first electrode that is transparent and conductive is formed on the insulation pattern to be electrically connected to the output terminal. A second electrode including silver (Ag) is formed on the first electrode to be electrically connected to the first electrode, and a protective layer is formed on the second electrode to cover at least a portion of the second electrode.

In still another aspect of the present invention, a display panel includes an array substrate, a counter substrate and a liquid crystal layer. The array substrate includes a first base substrate, a signal-applying module disposed on the first base substrate and including an output terminal configured to output a data signal, a first electrode disposed on the first base substrate and electrically connected to the output terminal, a second electrode disposed on the first electrode and electrically connected to the first electrode, and a protective layer disposed on the second electrode to cover at least a portion of the second electrode. The second electrode includes silver (Ag). The counter substrate includes a second base substrate facing the first base substrate, and a common electrode disposed on the second base substrate and facing the first and second electrodes. The liquid crystal layer is disposed between the first and second substrates.

In still another aspect of the present invention, a liquid crystal display device includes a display panel and a backlight assembly. The display panel displays an image using light. The display panel includes an array substrate, a counter substrate and a liquid crystal layer. The array substrate includes a first base substrate, a signal-applying module disposed on the first base substrate and including an output terminal configured to output a data signal, a transparent electrode disposed on the first base substrate and electrically connected to the output terminal, a reflective electrode disposed on the transparent electrode and electrically connected to the transparent electrode, and a protective layer disposed on the reflective electrode to cover at least a portion of the reflective electrode. The reflective electrode includes silver (Ag). The counter substrate includes a second base substrate facing the first base substrate, and a common electrode disposed on the second base substrate and facing the transparent and reflective electrodes. The liquid crystal layer is disposed between the first and second substrates. The backlight assembly provides the light to the display panel.

According to the above, the protective layer is formed on the second electrode including silver, thereby preventing yellowishness of the second electrode through following processes. In addition, the first electrode including indium tin oxide (ITO), amorphous indium tin oxide (a-ITO) or the like is formed beneath the second electrode, thereby improving adhesion of the reflective electrode to a lower layer.

### BRIEF DESCRIPTION OF THE DRAWINGS

The above and other features and advantage points of the present invention will become more apparent by describing in detailed example embodiments thereof with reference to the accompanying drawings, in which:

FIG. 1 is a plan view illustrating a portion of an array substrate according to a first example embodiment of the present invention;

FIG. 2 is a cross-sectional view taken along a line I-I′ in FIG. 1;

FIG. 3 is a cross-sectional view illustrating a portion of an array substrate according to a second example embodiment of the present invention;

FIG. 4 is a plan view illustrating a portion of an array substrate according to a third example embodiment of the present invention;

FIG. 5 is a cross-sectional view taken along a line II-II′ in FIG. 4;

FIG. 6 is a cross-sectional view illustrating a portion of an array substrate according to a fourth example embodiment of the present invention;

FIGS. 7 to 10 are cross-sectional views illustrating a method of manufacturing an array substrate according to a fifth example embodiment of the present invention;

FIG. 11A is a photograph showing a base substrate on which a single layer including silver is formed;

FIG. 11B is a photograph showing a base substrate on which a double layer including silver and indium tin oxide is formed;

FIG. 12 is a cross-sectional view illustrating a display panel according to a sixth example embodiment of the present invention; and

FIG. 13 is a cross-sectional view illustrating a liquid crystal display device according to a seventh example embodiment of the present invention.

### DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, region or substrate is referred to as being “on” or “onto” another element, it may be directly on the other element or intervening elements may also be present.

Array Substrate

### Embodiment 1

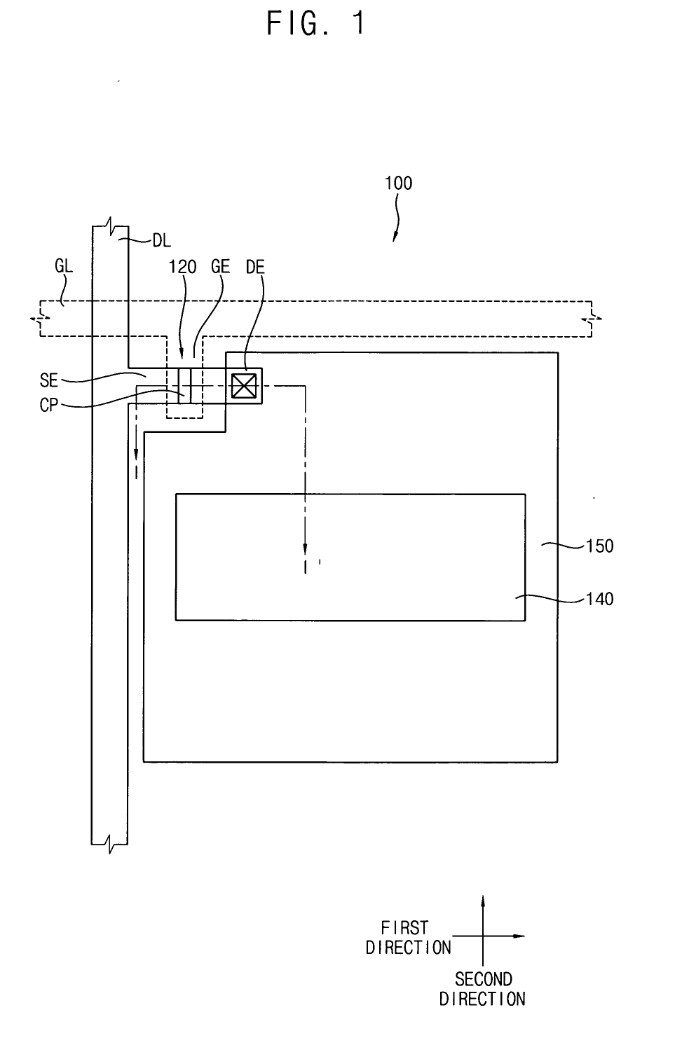

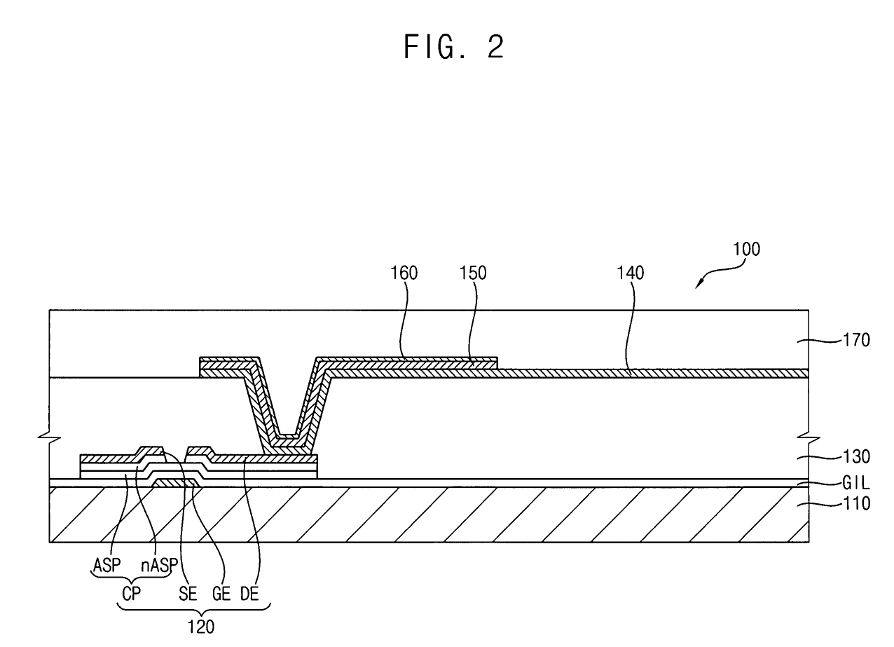

FIG. 1 is a plan view illustrating a portion of an array substrate according to a first example embodiment of the present invention. FIG. 2 is a cross-sectional view taken along a line I-I′ in FIG. 1.

Referring to FIGS. 1 and 2, an array substrate 100 includes a base substrate 110, a signal-applying module 120, an insulation pattern 130, a first electrode 140 and a second electrode 150 and a protective layer 160.

The base substrate 110 includes a transparent substrate such as a glass substrate capable of passing light.

The signal-applying module 120 is disposed on the base substrate 110. The signal-applying module 120 outputs an image data signal externally provided via an output terminal at a predetermined time.

In the present embodiment, the signal-applying module 120 includes a gate electrode GE, a gate insulation layer GIL, a channel pattern CP, a source electrode SE, and a drain electrode DE that is the output terminal.

The gate electrode GE protrudes from a gate line GL receiving a timing signal. The source electrode SE protrudes from a data line DL to output a data signal to the channel pattern CP.

The gate line GL extends in a first direction shown in FIG. 1. Although not shown in FIG. 1, a plurality of gate lines GL corresponding to a resolution of the array substrate 100 are substantially parallelly arranged in a second direction that is substantially perpendicular to the first direction. Although not shown in FIG. 1, a plurality of gate electrodes GE corresponding to the resolution of the array substrate 100 protrudes from each gate line GL on the base substrate 110 in a direction that is substantially in parallel with the second direction.

The gate insulation layer GIL covers the gate line GL having the gate electrode GE to insulate the gate line GL from the data line DL having the source electrode SE. The gate insulation layer GIL includes, for example, transparent silicon nitride.

The channel pattern CP is formed on the gate insulation layer GIL. The channel pattern CP, for example, is disposed on the gate insulation layer GIL corresponding to the gate electrode GE. The channel pattern CP includes an amorphous silicon pattern ASP and a pair of n+ amorphous silicon patterns nASP. The n+ amorphous silicon patterns nASP are disposed on the amorphous silicon pattern ASP, and spaced apart from each other.

The data line DL is disposed in the second direction on the gate insulation layer GIL. Although not shown in FIG. 1, a plurality of data lines DL corresponding to the resolution of the array substrate 100 is substantially parallelly arranged in the first direction. Although not shown in FIG. 1, a plurality of source electrodes SE corresponding to the resolution of the array substrate 100 protrudes from each data line DL on the base substrate 110 in a direction that is substantially in parallel with the first direction. Each source electrode SE is electrically connected to one of the n+ amorphous silicon patterns nASP.

The drain electrode DE is electrically connected to the other of the n+ amorphous silicon patterns nASP. The drain electrode DE is formed simultaneously with the data line DL, and is spaced apart form the source electrode SE.

The insulation pattern 130 is disposed on the base substrate 110 having the signal-applying module 120. A contact hole is formed through the insulation pattern 130 to expose the drain electrode DE of the signal-applying module 120. The insulation pattern 130 includes, for example, a photosensitive material that is sensitized to light so as to form the contact hole.

The first electrode 140 is disposed on the insulation pattern 130. The first electrode 140 is electrically connected to the drain electrode DE that is exposed by the contact hole. The first electrode 140 covers at least a portion of the insulation pattern 130.

The first electrode 140 includes a transparent conductive material. When light is provided from a lower part of the base substrate 110, the light passes through the transparent first electrode 140. Thus, the first electrode 140 may serve as a transparent electrode of a reflective-transmissive type liquid crystal display device.

The first electrode 140 includes, for example, at least one of indium tin oxide (ITO), amorphous indium tin oxide (a-ITO) and indium zinc oxide (IZO). When the first electrode 140 includes at least one of indium tin oxide (ITO), amorphous indium tin oxide (a-ITO) and indium zinc oxide (IZO), an adhesion of the second electrode 150 including silver (Ag) to a lower layer is improved. The second electrode 150 will be described later.

The first electrode 140 has, for example, a thickness of between about 40 nm to about 70 nm.

The second electrode 150 is disposed on the first electrode 140, and electrically connected to the first electrode 140. The second electrode 150 covers at least a portion of the first electrode 140.

The second electrode 150 includes silver (Ag). Generally, silver has a greater reflectivity than aluminum (Al) or aluminum alloy. When light is provided from an upper part of the base substrate 110, the light is reflected on the second electrode 150. Thus, the second electrode 150 may serve as a reflective electrode of a reflective-transmissive type liquid crystal display device.

Although silver has a greater reflectivity than aluminum (Al) or aluminum alloy, silver has a weak adhesion to many materials. However, silver has a strong adhesion, for example, to indium tin oxide (ITO), amorphous indium tin oxide (a-ITO) and indium zinc oxide (IZO). Thus, when the first electrode 140 including at least one of indium tin oxide (ITO), amorphous indium tin oxide (a-ITO) and indium zinc oxide (IZO) is disposed beneath the second electrode 150 including silver, the second electrode 150 may be strongly adhered to the first electrode 140. Hence, a lift off of the second electrode 150, which may occur in case of a weak adhesion to the first electrode 140, may be prevented.

The second electrode 150 has, for example, a thickness of between about 200 nm to about 300 nm.

The protective layer 160 is disposed on the second electrode 150, and is formed to correspond to the second electrode 150. The protective layer 160 includes a transparent conductive material, which may include at least one of indium tin oxide (ITO), amorphous indium tin oxide (a-ITO) and indium zinc oxide (IZO).

Advantageously, yellowishness of the second electrode 150 including silver (Ag) can be prevented because the protective layer 160 is disposed on the second electrode 150 and may serve as a capping layer of the second electrode 150.

The protective layer 160 may be etched and patterned simultaneously with the second electrode 150. A layer including silver, such as second electrode 150, can be rapidly etched by many etchants, and thus, the protective layer 160 on the may delay the etching time of silver in the second electrode 150. The protective layer 160 has, for example, a thickness of between about 30 nm to about 50 nm, and is constituted to delay the etching time.

In the present embodiment, the second electrode 150 and the protective layer 160 are formed at a peripheral portion of a pixel that is defined by the gate lines GL and the data lines DL. Thus, as shown in FIG. 1, the second electrode 150 and the protective layer 160 include an opening. Alternatively, the second electrode 150 and the protective layer 160 may include a plurality of openings. For example, each of the openings has a polygon shape.

An alignment layer 170 may be formed on the array substrate 100 successively having the first electrode 140, the second electrode 150 and the protective layer 160. The alignment layer 170 includes, for example, polyimide resin. A plurality of alignment grooves is formed on the alignment layer 170 to align liquid crystal molecules.

The array substrate 100 according to the present embodiment may be employed in a display panel of a reflective-transmissive type liquid crystal display device having both a reflective region and a transmissive region. Alternatively, the array substrate 100 may be employed in a display panel of a reflective type liquid crystal display device only having a reflective region. Here, the second electrode 150 of the array substrate 100 may cover substantially the entire portion of the first electrode 140.

### Embodiment 2

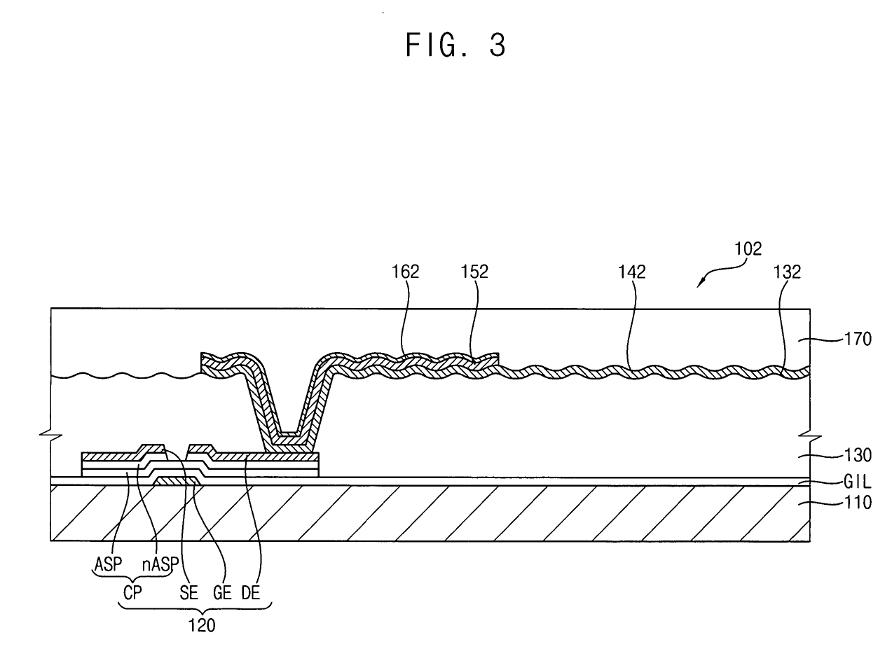

FIG. 3 is a cross-sectional view illustrating a portion of an array substrate 102 according to a second example embodiment of the present invention. The array substrate 102 in FIG. 3 is substantially the same as the array substrate 100 illustrated in FIGS. 1 and 2 except for shapes imparted to an insulation pattern, a first electrode, a second electrode, and a protective layer. Thus, any further descriptions for substantially the same elements will be omitted.

Referring to FIG. 3, an array substrate 102 includes a base substrate 110, a signal-applying module 120, an insulation pattern 130, a first electrode 142 and a second electrode 152 and a protective layer 162.

A plurality of embossing patterns 132 is formed on the insulation pattern 130. The first electrode 142 and the second electrode 152 and the protective layer 162 are successively disposed on the insulation pattern 130 having the embossing patterns 132.

The embossing patterns 132 may increase a reflective area of the second electrode 152, and diffuse light reflected on the second electrode 152.

### Embodiment 3

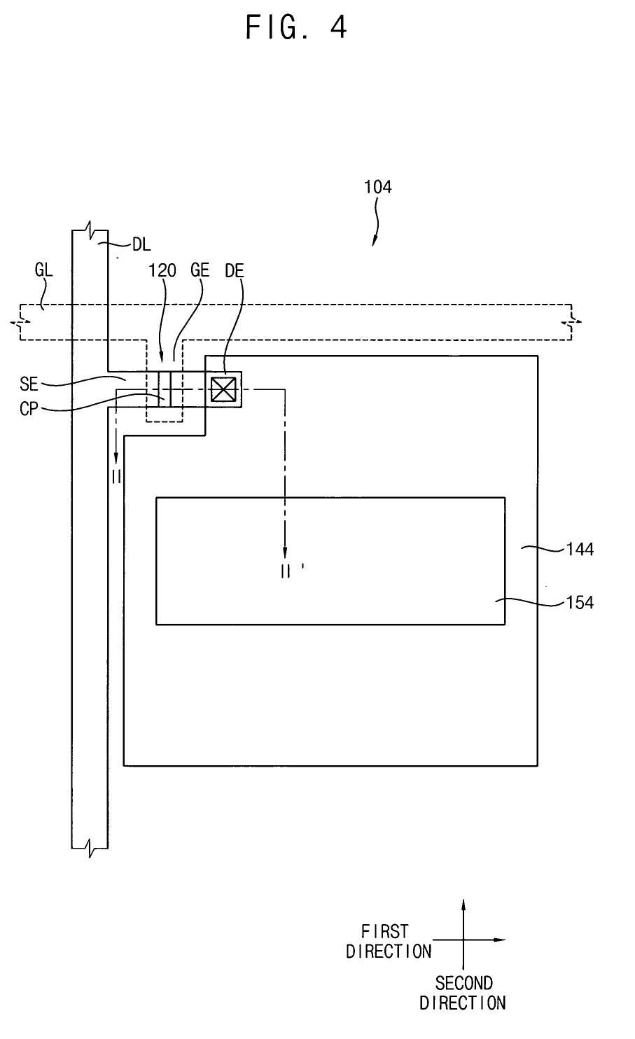

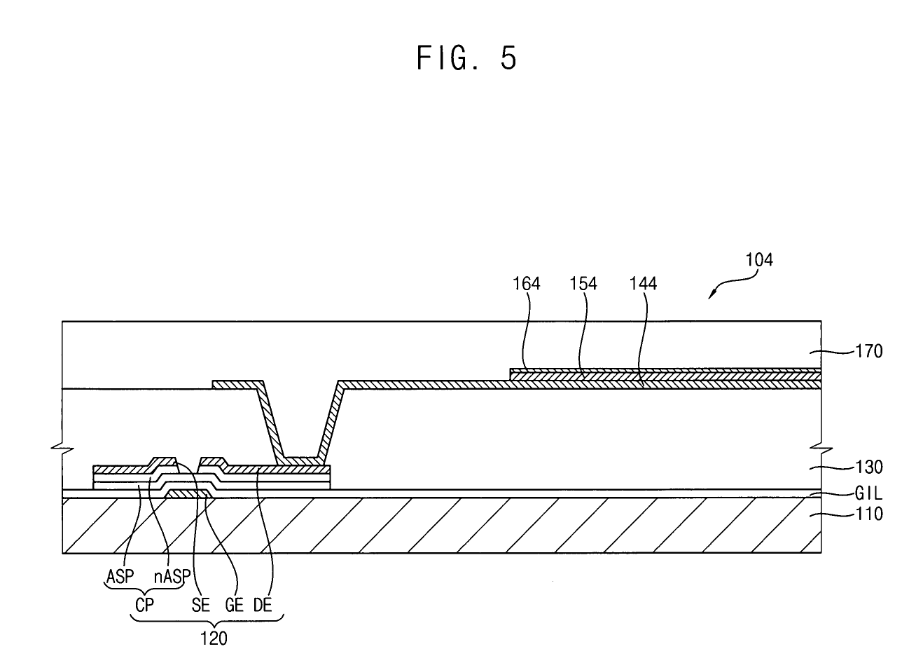

FIG. 4 is a plan view illustrating a portion of an array substrate 104 according to a third example embodiment of the present invention. FIG. 5 is a cross-sectional view taken along a line II-II′ in FIG. 4. The array substrate 104 in FIGS. 4 and 5 is substantially the same as the array substrate 100 illustrated in FIGS. 1 and 2 except for positions of a second electrode and a protective layer. Thus, any further descriptions for substantially the same elements will be omitted.

Referring to FIGS. 4 and 5, an array substrate 104 includes a base substrate 110, a signal-applying module 120, an insulation pattern 130, a first electrode 144 and a second electrode 154 and a protective layer 164.

In the present embodiment, the second electrode 154 and the protective layer 164 are formed at a central portion of a pixel that is defined by gate lines GL and data lines DL.

### Embodiment 4

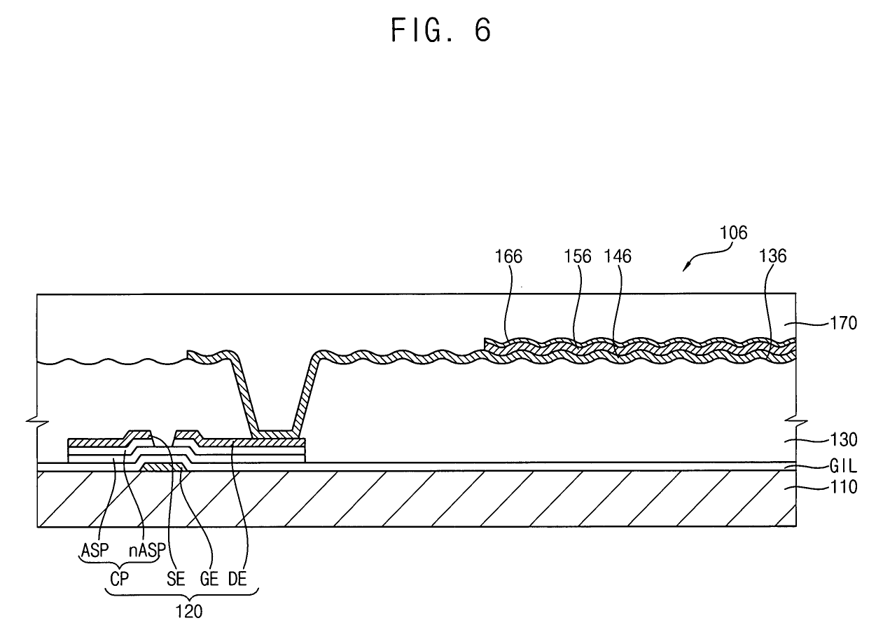

FIG. 6 is a cross-sectional view illustrating a portion of an array substrate 106 according to a fourth example embodiment of the present invention. The array substrate 106 in FIG. 6 is substantially the same as the array substrate 104 illustrated in FIGS. 4 and 5 except for shapes of an insulation pattern, a first electrode, a second electrode and a protective layer. Thus, any further descriptions for substantially the same elements will be omitted.

Referring to FIG. 6, an array substrate 106 includes a base substrate 110, a signal-applying module 120, an insulation pattern 130, a first electrode 146, a second electrode 156, and a protective layer 166.

A plurality of embossing patterns 136 is formed on the insulation pattern 130. The first electrode 146 and the second electrode 156 and the protective layer 166 are successively disposed on the insulation pattern 130 having the embossing patterns 136.

The embossing patterns 136 may increase a reflective area of the second electrode 156, and diffuse light reflected on the second electrode 156.

Method of Manufacturing an Array Substrate

### Embodiment 5

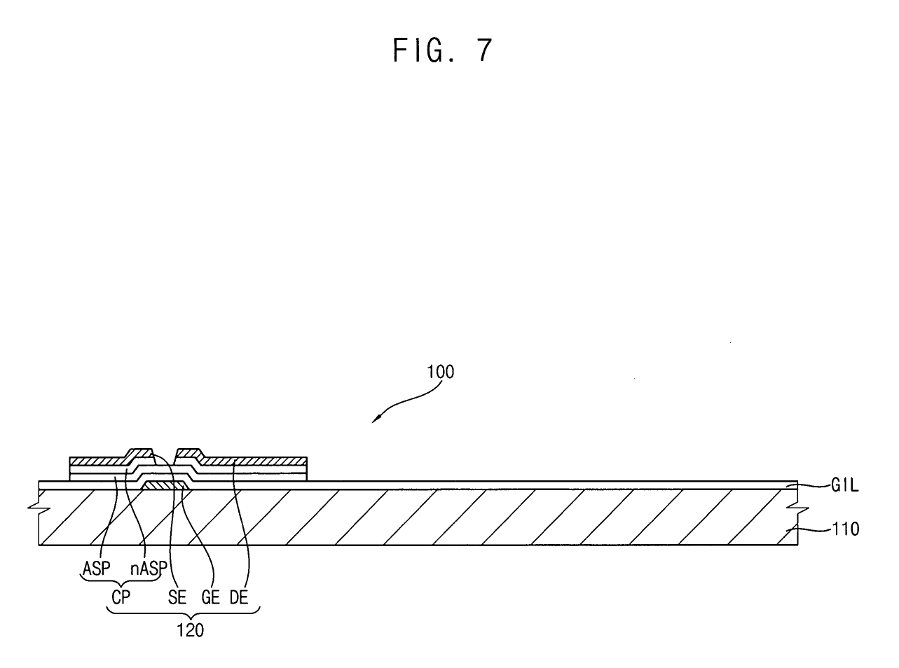

FIGS. 7 to 10 are cross-sectional views illustrating a method of manufacturing an array substrate according to a fifth exemplary embodiment of the present invention. Although a method of manufacturing the array substrate 100 illustrated in FIGS. 1 and 2 will be described in detail in the present embodiment, the array substrate 104 illustrated in FIGS. 4 and 5 may be manufactured by substantially the same method.

Referring to FIG. 7, in order to manufacture the array substrate 100, first, a signal-applying module 120 is formed on the base substrate 110.

In order to form the signal-applying module 120, a gate metal (not shown) is formed on the base substrate 110 through a chemical vapor deposition (CVD) process or a sputtering process. The gate metal includes, for example, aluminum (Al) or molybdenum (Mo).

The gate metal is patterned through a photolithography process to form the gate line GL and the gate electrode GE protruding from the gate line GL on the base substrate 110.

Then, the gate insulation layer GIL is formed on the base substrate 110 through a CVD process. The gate insulation layer GIL includes, for example, a transparent silicon nitride.

An n+ amorphous silicon layer (not shown), an amorphous silicon layer (not shown) and a source/drain layer (not shown) are successively formed on the gate insulation layer GIL.

The source/drain layer is patterned through a photolithography process to form the data line DL, the source electrode SE protruding from the data line DL and the drain electrode DE spaced apart from the source electrode SE on the n+ amorphous silicon layer.

The n+ amorphous silicon layer and the amorphous silicon layer are patterned using a mask of the data line DL and the drain electrode DE. Thus, the channel pattern CP including the n+ amorphous silicon pattern nASP and the amorphous silicon pattern ASP is formed on the gate insulation layer GIL.

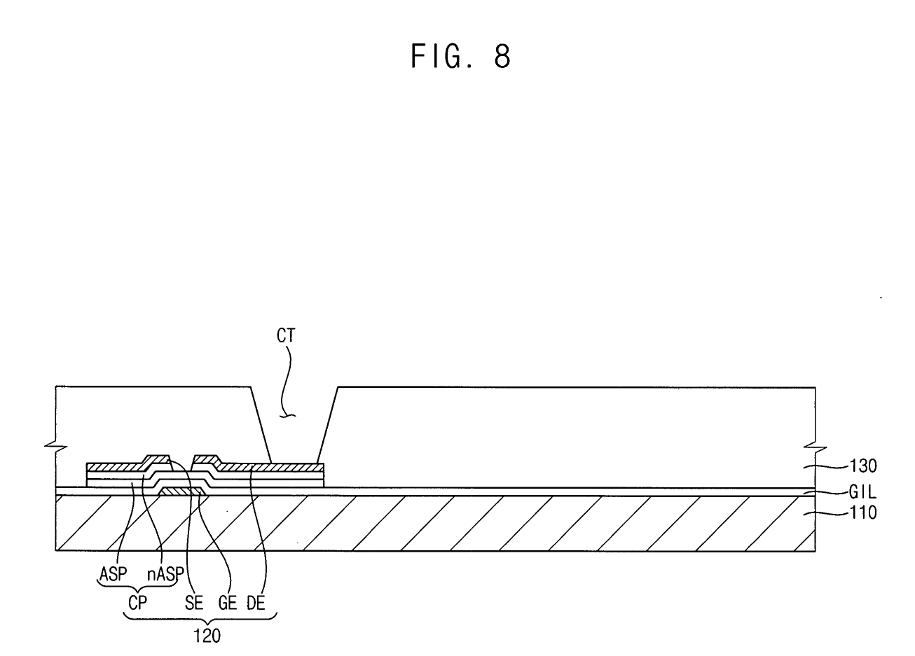

Referring to FIG. 8, a thick insulation layer (not shown) is formed on the base substrate 110. The insulation layer includes, for example, an organic layer having photosensitive material that is sensitized to light. Alternatively, the insulation layer may include a double layer that has an inorganic layer such as silicon nitride layer and an organic layer. The insulation layer formed on the base substrate 110 is patterned by light passing through a predetermined mask to form the insulation pattern 130. A contact hole CT exposing a portion of the drain electrode DE of the signal-applying module 120 is formed through the insulation pattern 130.

In the present embodiment, an embossing pattern is not formed on the insulation pattern 130. Alternatively, a plurality of embossing patterns 132 illustrated in FIG. 3 may be formed on the insulation pattern 130. In addition, when manufacturing the array substrate 104 illustrated in FIGS. 4 and 5, the embossing patterns 136 illustrated in FIG. 6 may also be formed on the insulation pattern 130.

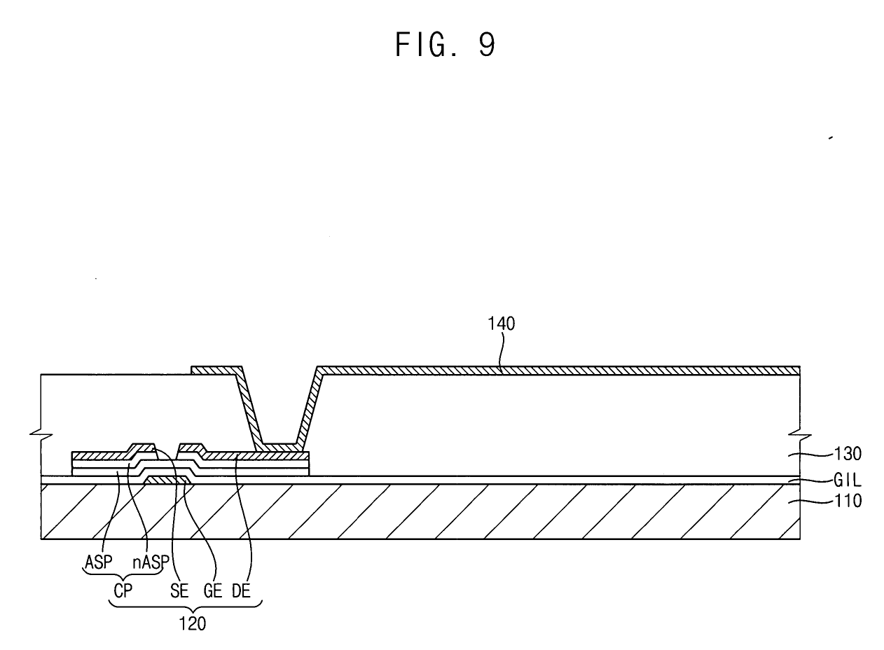

Referring to FIG. 9, the first electrode 140 is formed on the insulation pattern 130. The first electrode 140 is formed to have, for example, a thickness of between about 40 nm to about 70 nm.

The first electrode 140 includes a transparent conductive material. The first electrode 140 includes, for example, indium tin oxide (ITO) or amorphous indium tin oxide (a-ITO).

When the first electrode 140 includes indium zinc oxide (IZO), the first electrode 140 may be etched and deteriorated in etching the second electrode 150 that will be described later.

When the first electrode 140 includes indium tin oxide (ITO), the first electrode 140 typically is etched using aqua regia. During an etch using the aqua regia, a lower layer disposed under the first electrode 140 also may be deteriorated by the aqua regia.

Alternatively, when the first electrode 140 includes amorphous indium tin oxide (a-ITO), the first electrode 140 may be etched using a weak acid, which may prevent the lower layer disposed under the first electrode 140 from being deteriorated.

When the first electrode 140 includes amorphous indium tin oxide (a-ITO), the first electrode 140 may be heat-treated under a predetermined condition. In an exemplary predetermined condition, the first electrode 140 is hard baked at a temperature of about 200° C. for about two hours.

After hard baking the first electrode 140, amorphous indium tin oxide (a-ITO) is changed into poly indium tin oxide (poly-ITO). Advantageously, when the first electrode 140, including amorphous indium tin oxide (a-ITO), is hard baked at a high temperature for a long time as in the exemplary predetermined condition, the first electrode 140 is not easily etched by a silver etchant. Beneficially, the thickness of the first electrode 140 can be made sufficiently thick such that the first electrode 140 is not easily etched by the silver etchant.

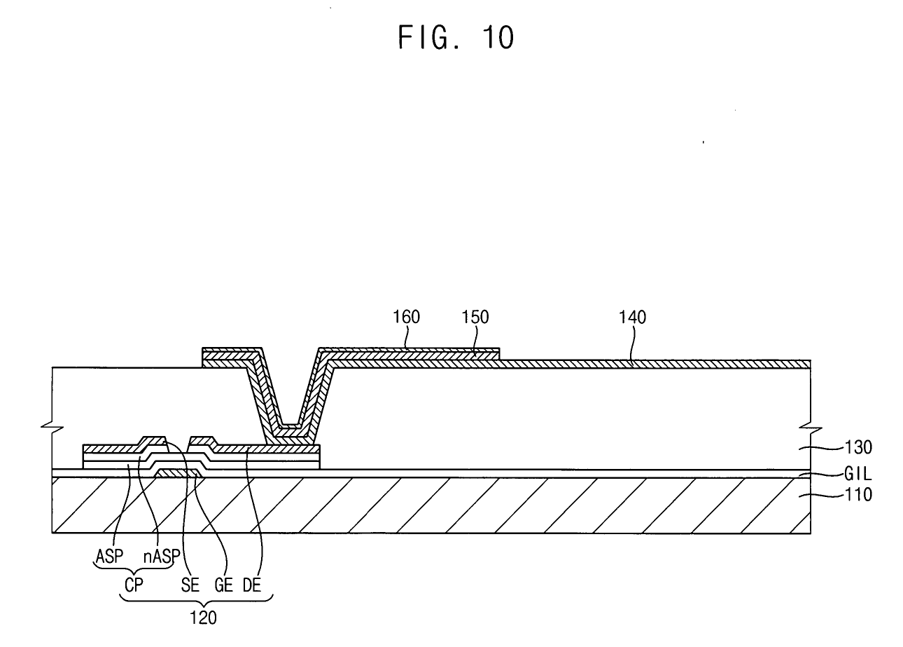

Referring to FIG. 10, the second electrode 150 and the protective layer 160 are formed on the first electrode 140.

The second electrode 150 includes silver (Ag), and the protective layer 160 may include a transparent conductive material. The protective layer 160 includes, for example, indium tin oxide (ITO) or amorphous indium tin oxide (a-ITO).

A preliminary second electrode layer (not shown), for example, is deposited at below about 50° C., and a preliminary protective layer (not shown), for example, is deposited at a normal temperature. The preliminary second electrode layer and the preliminary protective layer indicate the second electrode 150 and the protective layer 160 before being etched and patterned, respectively.

After the preliminary second electrode layer and the preliminary protective layer are deposited, the preliminary second electrode layer and the preliminary protective layer are patterned through a readily available photolithography process. The preliminary second electrode layer and the preliminary protective layer are simultaneously etched using a known silver etchant. The silver etchant includes, for example, at least one of phosphoric acid, nitric acid, acetic acid and hydrogen peroxide.

A layer including silver is rapidly etched by many etchants. Thus, since the preliminary protective layer is formed on and is simultaneously etched with the preliminary second electrode layer including silver, the preliminary protective layer may delay an etching time of the preliminary second electrode layer, which includes silver. The preliminary second electrode layer has, for example, a thickness of between about 200 nm to about 300 nm, and the preliminary protective layer has, for example, a thickness of between about 30 nm to about 50 nm, so as to delay the etching time of the preliminary second electrode layer.

The preliminary second electrode layer and the preliminary protective layer are patterned to form the second electrode 150 and the protective layer 160.

The second electrode 150, which includes silver, has a weak adhesion to many materials. However, the second electrode 150 may be strongly adhered to the first electrode 140, when the first electrode 140 includes, without limitation, indium tin oxide (ITO), amorphous indium tin oxide (a-ITO) or indium zinc oxide (IZO).

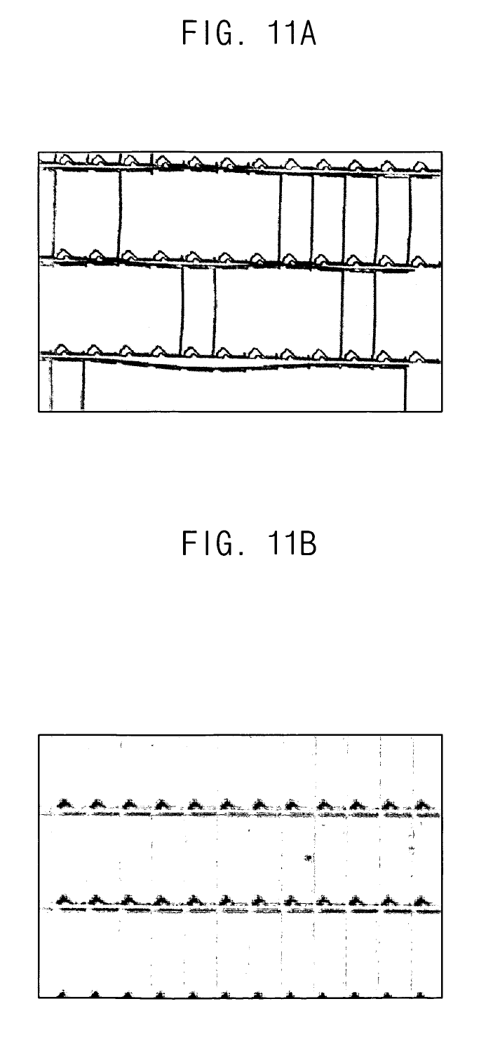

FIG. 11A is a photograph showing a base substrate on which a single layer including silver is formed. FIG. 11B is a photograph showing a base substrate on which a double layer including silver and indium tin oxide is formed.

Referring to FIGS. 11A and 11B within the exemplary contexts of FIG. 1 and FIG. 2, when the second electrode 150 is formed on the insulation pattern 130, the second electrode 150 may be lifted off because the second electrode 150 has a weak adhesion to the insulation pattern 130. In contrast, when the second electrode 150 is formed on the first electrode 140, a lift off of the second electrode 150 may be prevented because the second electrode 150 has a strong adhesion to the first electrode 140, and distortion of a pattern shape of the second electrode 150 is prevented thereby.

The alignment layer 170 may be formed on the array substrate 100 successively having the first electrode 140, the second electrode 150 and the protective layer 160. For example, the alignment layer 170 includes polyimide resin. A plurality of alignment grooves (not shown) are formed on the alignment layer 170 so as to align liquid crystal molecules.

Display Panel

### Embodiment 6

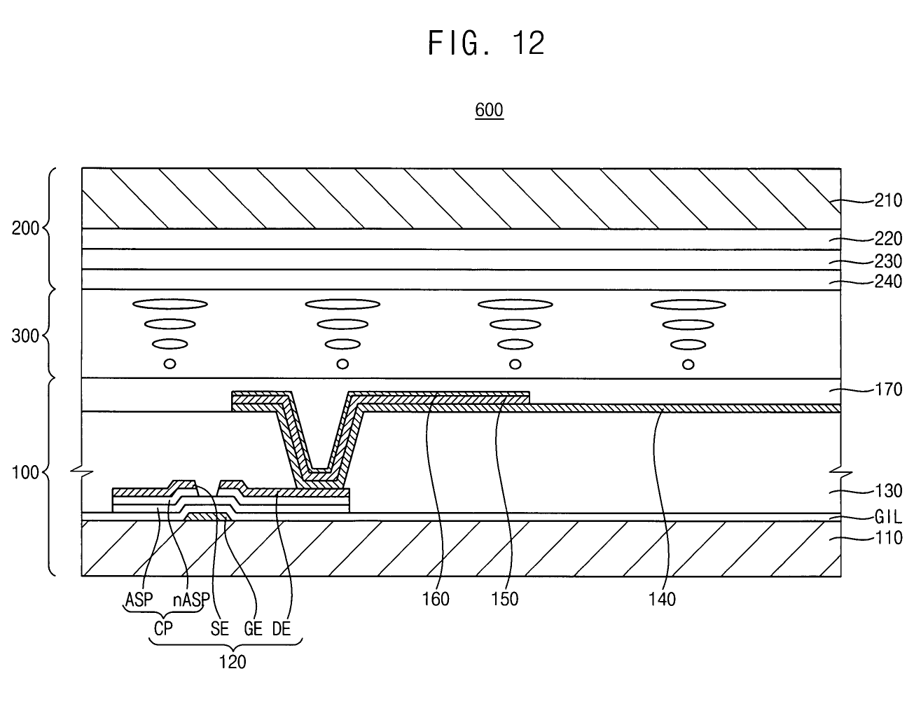

FIG. 12 is a cross-sectional view illustrating a display panel 600 according to a sixth exemplary embodiment of the present invention.

Referring to FIG. 12, a display panel 600 includes an array substrate 100, a counter substrate 200 and a liquid crystal layer 300.

The array substrate 100 includes a first base substrate 110, a signal-applying module 120, an insulation pattern 130, a first electrode 140, a second electrode 150, a protective layer 160, and a first alignment layer 170. The array substrate 100 is substantially the same as the array substrate 100 illustrated in FIGS. 1 and 2. Thus, any further description for substantially the same elements will be omitted.

The counter substrate 200 includes a second base substrate 210, a color filter 220, a common electrode 230 and a second alignment layer 240.

The second base substrate 210 includes a transparent substrate such as a glass substrate capable of passing light.

The color filter 220 is disposed on the second base substrate 210. The color filter 220 includes, for example, a red color filter for passing red light of white light, a green color filter for passing green light of white light, and a blue color filter for passing blue light of white light.

The common electrode 230 is formed on the color filter 220. The common electrode 230 may include a transparent conductive material. The common electrode 230 includes, without limitation, at least one of indium tin oxide (ITO), amorphous indium tin oxide (a-ITO) and indium zinc oxide. The common electrode 230 faces the first and second electrodes 140 and 150 of the array substrate 100.

The second alignment layer 240 is disposed to face the first alignment layer 170. Alignment grooves are formed on the second alignment layer 240 so as to align liquid crystal molecules of the liquid crystal layer 300.

The liquid crystal layer 300 is disposed between the array substrate 100 and the counter substrate 200.

In the present embodiment, the display panel 600 employs the array substrate 100 of Embodiment 1. Alternatively, the display panel 600 may employ the array substrates 102, 104 and 106 of Embodiment 2, 3 and 4, respectively.

Liquid Crystal Display Device

### Embodiment 7

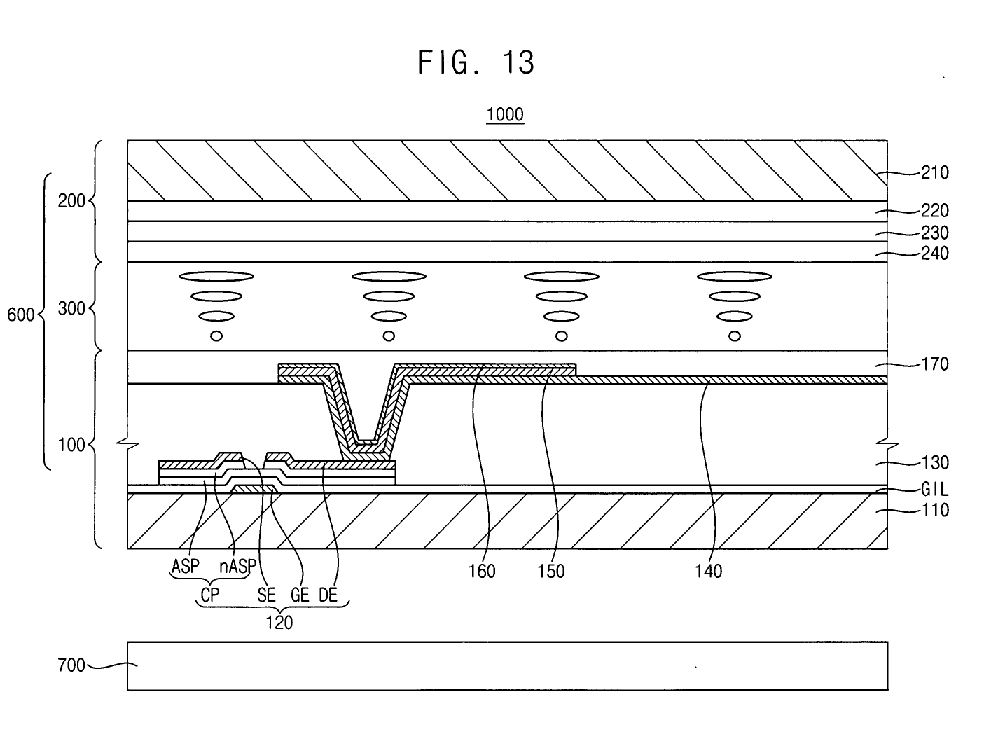

FIG. 13 is a cross-sectional view illustrating a liquid crystal display device 1000, according to a seventh example embodiment of the present invention.

Referring to FIG. 13, a liquid crystal display device 1000 includes a display panel 600 and a backlight assembly 700.

The display panel 600 includes an array substrate 100, a counter substrate 200 and a liquid crystal layer 300. The display panel 600 is substantially the same as the display panel 600 illustrated in FIG. 12. Thus, any further description for substantially the same elements will be omitted.

The backlight assembly 700 provides light to the display panel 600. The liquid crystal display device 1000 may display an image using the light provided from the backlight assembly 700 and/or using externally provided light.

According to the present invention, a protective layer is formed on a reflective electrode including silver, thereby preventing yellowishness of the reflective electrode through following processes.

In addition, a transparent electrode including indium tin oxide (ITO), amorphous indium tin oxide (a-ITO) or the like is formed beneath the reflective electrode, thereby improving adhesion of the reflective electrode to a lower layer.

Although exemplary embodiments of the present invention have been described, it is understood that the present invention should not be limited to these example embodiments but various changes and modifications can be made by one ordinary skilled in the art within the spirit and scope of the present invention as hereinafter claimed.

What is claimed is:

1. An array substrate for a display panel comprising:
a base substrate;
a signal-applying module disposed on the base substrate and comprising an output terminal configured to output a data signal;
a first electrode disposed on the base substrate and electrically connected to the output terminal;
a second electrode disposed on the first electrode and electrically connected to the first electrode, wherein the second electrode includes silver (Ag); and
a protective layer disposed on the second electrode to cover at least a portion of the second electrode.

2. The array substrate of claim 1, wherein the signal-applying module further comprises:
a gate electrode protruding from a gate line that receives a timing signal;
a gate insulation layer configured to insulate the gate electrode;
a channel layer disposed on the gate insulation layer corresponding to the gate electrode; and
a source electrode protruding from a data line to output the data signal to the channel layer,
wherein the output terminal is a drain electrode spaced apart from the source electrode.

3. The array substrate of claim 1, further comprising an insulation pattern having a contact hole that exposes the output terminal.

4. The array substrate of claim 3, wherein the first electrode is disposed on the insulation pattern.

5. The array substrate of claim 3, wherein an embossing pattern is formed on the insulation pattern.

6. The array substrate of claim 1, wherein the second electrode covers at least a portion of the first electrode.

7. The array substrate of claim 6, wherein the first electrode comprises a first electrode that is transparent and conductive.

8. The array substrate of claim 7, wherein the first electrode includes at least one of indium tin oxide and amorphous indium tin oxide.

9. The array substrate of claim 1, wherein the protective layer includes at least one of indium tin oxide and amorphous indium tin oxide.

10. The array substrate of claim 1, wherein the protective layer has a thickness of between about 30 nm to about 50 nm.

11. The array substrate of claim 1, wherein the second electrode has a thickness of between about 200 nm to about 300 nm.

12. A method of manufacturing an array substrate for a display panel, comprising:
forming a signal-applying module on a base substrate, the signal-applying module comprising an output terminal configured to output a data signal;
forming a contact hole that exposes a portion of the output terminal through an insulation layer covering the signal-applying module to form an insulation pattern;
forming a first electrode that is transparent and conductive on the insulation pattern to be electrically connected to the output terminal; and
forming a second electrode on the first electrode to be electrically connected to the first electrode, and a protective layer on the second electrode to cover at least a portion of the second electrode, the second electrode including silver (Ag).

13. The method of claim 12, wherein forming the insulation pattern further comprising forming an embossing pattern on the insulation layer.

14. The method of claim 12, wherein the second electrode is formed to cover at least a portion of the first electrode.

15. The method of claim 12, further comprising hard baking the first electrode after forming the first electrode.

16. The method of claim 12, wherein the second electrode and the protective layer are formed by:
forming a preliminary second electrode layer on the first electrode;
forming a preliminary protective layer on the preliminary second electrode layer; and
simultaneously etching and patterning the preliminary second electrode layer and the preliminary protective layer.

17. The method of claim 16, wherein the preliminary second electrode layer and the preliminary protective layer are etched by at least one of phosphoric acid, nitric acid, acetic acid and hydrogen peroxide.

18. The method of claim 12, wherein the protective layer has a thickness of between about 30 nm to about 50 nm.

19. The method of claim 12, wherein the second electrode has a thickness of between about 200 nm to about 300 nm.

20. The method of claim 12, wherein the first electrode and the protective layer include amorphous indium tin oxide.

21. A display panel comprising:
an array substrate comprising:
a first base substrate;
a signal-applying module disposed on the first base substrate and comprising an output terminal configured to output a data signal;
a first electrode disposed on the first base substrate and electrically connected to the output terminal;
a second electrode disposed on the first electrode and electrically connected to the first electrode, wherein the second electrode includes silver (Ag); and
a protective layer disposed on the second electrode to cover at least a portion of the second electrode;
a counter substrate comprising:
a second base substrate facing the first base substrate; and
a common electrode disposed on the second base substrate and facing the first and second electrodes; and
a liquid crystal layer disposed between the first and second substrates.

22. The display panel of claim 21, wherein the array substrate further comprises an insulation pattern having a contact hole that exposes the output terminal.

23. The display panel of claim 21, wherein the protective layer has a thickness of between about 30 nm to about 50 nm, and the second electrode has a thickness of between about 200 nm to about 300 nm.

24. The display panel of claim 21, wherein the second electrode covers at least a portion of the first electrode.

25. A liquid crystal display device comprising:
a display panel configured to display an image using light, the display panel comprising:
an array substrate comprising a first base substrate, a signal-applying module disposed on the base substrate and comprising an output terminal configured to output a data signal, a transparent electrode disposed on the first base substrate and electrically connected to the output terminal, a reflective electrode disposed on the transparent electrode and electrically connected to the transparent electrode, and a protective layer disposed on the reflective electrode to cover at least a portion of the reflective electrode, wherein the reflective electrode includes silver (Ag);
a counter substrate comprising a second base substrate facing the first base substrate, and a common electrode disposed on the second base substrate and facing the transparent and reflective electrodes; and
a liquid crystal layer disposed between the first and second substrates; and
a backlight assembly configured to provide the light to the display panel.

26. The liquid crystal display device of claim 25, wherein each of the transparent electrode and the protective layer includes at least one of indium tin oxide and amorphous indium tin oxide.

27. The liquid crystal display device of claim 25, wherein the protective layer has a thickness of between about 30 nm to about 50 nm, and the reflective electrode has a thickness of between about 200 nm to about 300 nm.
